(19) United States
(12) Patent Application Publication
(10) Pub. No.: US 2006/0176921 A1
(43) Pub. Date: Aug. 10, 2006

(54) Semiconductor laser device

(76) Inventors: Tetsuo Ueda, Ibaraki-shi (JP); Masahiro Kume, Otsu-shi (JP); Toshiya Kawata, Oakayama-shi (JP); Isao Kidoguchi, Kawanishi-shi (JP)

Correspondence Address: MCDERMOTT WILL & EMERY LLP, 600 13TH STREET, N.W., WASHINGTON, DC, 20005-3096, US

(21) Appl. No.: 11/335,828

(22) Filed: Jan. 20, 2006

(30) Foreign Application Priority Data
Jul. 9, 2003 (JP) 2003-272287

(51) Int. Cl. H01S 5/00

(52) U.S. Cl. 372/43.01

(57) ABSTRACT

To provide a semiconductor laser device for which a horizontal divergence angle of a laser beam can be improved independently of optimization of other properties such as a cladding layer thickness and a current injected region size. A current blocking layer covers a larger area of a p-type second cladding layer and p-type cap layer extending in a resonator length direction, on a light emitting end face side than on an opposite end face side. Thus, current uninjected regions are formed in an optical waveguide. The current blocking layer (current uninjected region) on the light emitting end face side is set long enough to prevent carriers, which flow in from a current injected region, from reaching alight emitting end face. In this way, a light intensity distribution of a near-field pattern on the light emitting end face is concentrated, thereby increasing a horizontal divergence angle of a laser beam.

This application is based on an application No. 2003-272287 filed in Japan, the contents of which are hereby incorporated by reference.

### BACKGROUND OF THE INVENTION

1. Field of the Invention

The present invention relates to a semiconductor laser device, and in particular relates to techniques for independently controlling increases in light output power and increases in horizontal divergence angle.

2. Related Art

Optical discs such as CD (Compact Disc) and DVD (Digital Versatile Disc) are widely used in recent years. Nowadays, optical discs gain widespread acceptance among consumers as media suitable for recording large-volume digital information represented by AV (Audio/Video) content information. As a result, demand for optical disc devices capable of writing onto optical discs is growing sharply.

A writing speed of an optical disc device can be improved by increasing light output power of a semiconductor laser device which is used in an optical pickup. Improvements in writing speed enhance user friendliness, thereby making products more appealing to consumers.

In view of this, higher light output power is increasingly required of, for example, AlGaAs semiconductor laser devices with a wavelength band of 780 nm used in optical pickups for CD-R (Recordable) and CD-RW (ReWritable) and InGaAlP semiconductor laser devices with a wavelength band of 650 nm used in optical pickups for DVD-R, DVD-RW, and DVD-RAM (Random Access Memory).

In addition to increases in light output power, semiconductor laser devices used in optical pickups are required to have as large a horizontal divergence angle θ∥ of an outgoing laser beam as possible. A desired horizontal divergence angle θ∥ is 7.5 decrees or more.

If the horizontal divergence angle θ∥ is small, it is difficult to concentrate a laser beam, and so a desired Optical coupling coefficient with a write pit on an optical disc cannot be attained. This causes problems such as noise and jitter.

To respond to these requirements, semiconductor laser devices are conventionally disclosed (e.g. Japanese Patent Application Publication No. 2003-78208, hereafter referred to as “patent document 1”).

The patent document 1 discloses a ridge-type semiconductor laser device which is roughly made up of a cladding layer of a first conductivity type, an active layer disposed on the cladding layer of the first conductivity type, a cladding layer of a second conductivity type disposed on the active layer and having a ridge that extends in a resonator length direction, and a current blocking layer disposed on both sides of the ridge. A current constricted by the current blocking layer is injected into the active layer through an upper surface of the ridge. This semiconductor laser device is characterized in that a layer thickness of the cladding layer of the first conductivity type is greater than a layer thickness of the cladding layer of the second conductivity type including the ridge.

In general, a ridge-type semiconductor laser device is known to have the following characteristics.

(a) A cross section of a ridge orthogonal to the resonator length direction is a trapezoid with an upper base shorter than a lower base.

(b) A laser beam of a larger horizontal divergence angle θ∥ can be obtained when the lower base is shortened.

(c) When the upper base is shortened, a region for injecting a current is reduced and an element resistance increases, which hinders increases in light output power.

Which is to say, when the ridge height is constant, increases in horizontal divergence angle θ∥ of a laser beam and increases in light output power are mutually contradictory.

In view of this contradictory relationship, the patent document 1 reduces the ridge height, thereby realizing a semiconductor laser device in which the lower base of the ridge cross section is short enough to attain a desired horizontal divergence angle θ∥ and the upper base of the ridge cross section is long enough to produce high output power.

### SUMMARY OF THE INVENTION

However, since this conventional technique simultaneously pursues desired horizontal divergence angle θ∥ and element resistance by reducing the ridge height, there may be cases where properties that are dependent on the ridge height cannot be optimized.

In detail, if the ridge height is reduced while fixing the lower base of the ridge cross section at a length that can produce a desired horizontal divergence angle θ∥, the element resistance decreases and as a result an operating voltage decreases, but a waveguide loss increases (see FIG. 6 of the patent document 1).

This increase in waveguide loss occurs because, as a result of reducing the ridge height, a laser beam exudes from the cladding layer of the second conductivity type to a contact layer and is absorbed into the contact layer.

Thus, the semiconductor laser device according to the conventional technique has a problem that it is impossible to independently manage the horizontal divergence angle θ∥, the element resistance, and the properties that are dependent on the ridge height. This complicates a work for finding an optimal construction of semiconductor laser devices, and inhibits efficient designing of semiconductor laser devices.

In view of the above problem, the present invention aims to provide a semiconductor laser device for which, having optimized properties that are dependent on a ridge height, a horizontal divergence angle θ∥ of a laser beam can be increased independently of the optimization of the ridge height-dependent properties.

The stated aim can be achieved by a semiconductor laser device including an optical resonator, the optical resonator including: an optical waveguide formed by laminating a cladding layer of a first conductivity type, an active layer, and a cladding layer of a second conductivity type in the stated order; and a pair of reflection planes formed by providing both a light emitting end face and an opposite end face of the optical waveguide with a reflection function, wherein a window region is formed in, of both end areas of the optical waveguide, at least an end area including the light emitting end face, by introduction of impurities. A length of the window region in the end area including the light emitting end face, measured in a resonator length direction, is set to prevent carriers which flow from a current injected region of the optical waveguide into the window region, from reaching the light emitting end face, or set to prevent carriers which are injected at an end of a gain region, from reaching the light emitting end face.

The resonator length direction referred to here is a direction of travel of a laser beam.

According to the above construction, the window region formed in the end area including the light emitting end face (i.e. the window region on the light emitting end face side) is made long enough to keep the carriers from reaching the light emitting end face. As a result, a light intensity distribution of a near-field pattern on the light emitting end face is more concentrated, which produces an effect of increasing a horizontal divergence angle of an outgoing laser beam.

This mechanism is explained below. In part of the window region where the carriers flow in, a refractive index drops and optical confinement weakens. Therefore, if the length of the window region is insufficient and the carriers reach the light emitting end face, the light intensity distribution of the near-field pattern on the light emitting end face is less concentrated. In this case, the horizontal divergence angle of a laser beam decreases.

According to the above construction, however, the window region in the end area including the light emitting end face is set long enough. Accordingly, the carriers are prevented from reaching the light emitting end face. In this case, the light intensity distribution of the near-field pattern on the light emitting end face is heavily concentrated in a ridge width center, with it being possible to increase the horizontal divergence angle of a laser beam.

Also, the length of the window region in the end area including the light emitting end face can be set independently of and without being constrained by parameters such as a cladding layer thickness and a current injected region size. Accordingly, the horizontal divergence angle can be increased by setting the length of the window region after optimizing the cladding layer thickness and the current injected region size.

This eases a work for finding an optimal construction of semiconductor laser devices. Hence designing of semiconductor laser devices can be conducted efficiently.

Here, in order to keep the carriers from reaching the light emitting end face, a current uninjected region may be formed in the end area including the light emitting end face, with the window region being included in the current uninjected region. Also, the current uninjected region may be covered by a current blocking layer.

Here, a length of the current uninjected region, measured in the resonator length direction, may be set to prevent carriers which flow from the current injected region of the optical waveguide into the current uninjected region, from reaching the light emitting end face.

In this way, the length of the window region in the end area including the light emitting end face can be set to keep the carriers from reaching the light emitting end face.

In other words, the above effect of increasing the horizontal divergence angle can also be achieved by making the current uninjected region in the end area including the light emitting end face long enough to keep the carriers, which flow in from the current injected region, from reaching the light emitting end face.

Here, the length of the current uninjected region may be no smaller than 30 μm, and more preferably no smaller than 35 μm.

Meanwhile, in order to reduce variations in astigmatism when the light output power changes, the length of the current uninjected region may be no greater than 45 μm.

Here, in addition to the window region in the end area including the light emitting end face, a window region may be formed in an end area including the opposite end face, by introduction of impurities. In this case, the window region in the end area including the opposite end face may be included in a current uninjected region formed in the optical waveguide.

Here, the window region in the end area including the light emitting end face may be longer than the window region in the end area including the opposite end face.

In so doing, a sufficient length of the window region in the end area including the light emitting end face can be ensured while limiting a total length of the two window regions to a small level.

By limiting the total length of the two window regions, a total current uninjected region length can be reduced, with it being possible to ensure a sufficient length of the current injected region. Such a sufficient length of the current injected region contributes to higher light output power.

That is, by making the window region in the end area including the light emitting end face longer than the window region in the end area including the opposite end face, a sufficient length of the former window region can be ensured while maintaining high light output power.

Here, in order to ensure a sufficient length of the current injected region, the length of the window region in the end area including the light emitting end face may be no greater than 10% of a total length of the optical resonator, or the total current uninjected region length may be no greater than 10% of the total length of the optical resonator.

### BRIEF DESCRIPTION OF THE DRAWINGS

These and other objects, advantages and features of the invention will become apparent from the following description thereof taken in conjunction with the accompanying drawings which illustrate a specific embodiment of the invention.

In the drawings:

FIG. 1 is a perspective view showing a semiconductor laser device to which an embodiment of the present invention relates;

FIG. 2 shows a cross section of the semiconductor laser device taken along line X1-X1′ in FIG. 1;

FIG. 3 is a conceptual view showing flows of carriers in a longitudinal section of the semiconductor laser device taken along line Z-Z′ in FIG. 1;

FIG. 4 is a conceptual view showing flows of carriers, a refractive index of an active layer, and a light intensity in the cross section of the semiconductor laser device taken along line X1-X1′;

FIG. 5 is a conceptual view showing flows of carriers, a refractive index of the active layer, and a light intensity in a cross section of the semiconductor laser device taken along line X2-X2′ in FIG. 1;

FIG. 6 is a conceptual view showing flows of carriers, a refractive index of the active layer, and a light intensity in a cross section of the semiconductor laser device taken along line X3-X3′ in FIG. 1;

FIG. 7 is a graph showing a relationship between a beam shaping region length and a COD/kink level of the semiconductor laser device;

FIG. 8 is a graph showing a relationship between a beam shaping region length and a horizontal divergence angle of the semiconductor laser device;

FIG. 9 is a graph showing a relationship between a beam shaping region length and an astigmatism of the semiconductor laser device;

FIG. 10 is a perspective view showing a dual wavelength semiconductor laser device to which the construction of the semiconductor laser device according to the embodiment is applied;

FIG. 11 is a perspective view showing a groove-type semiconductor laser device to which the construction of the semiconductor laser device according to the embodiment is applied; and

FIG. 12 is a perspective view showing a blue-violet semiconductor laser device to which the construction of the semiconductor laser device according to the embodiment is applied.

### DESCRIPTION OF THE PREFERRED EMBODIMENT(S)

The following describes a semiconductor laser device to which an embodiment of the present invention relates, with reference to drawings.

<Construction>

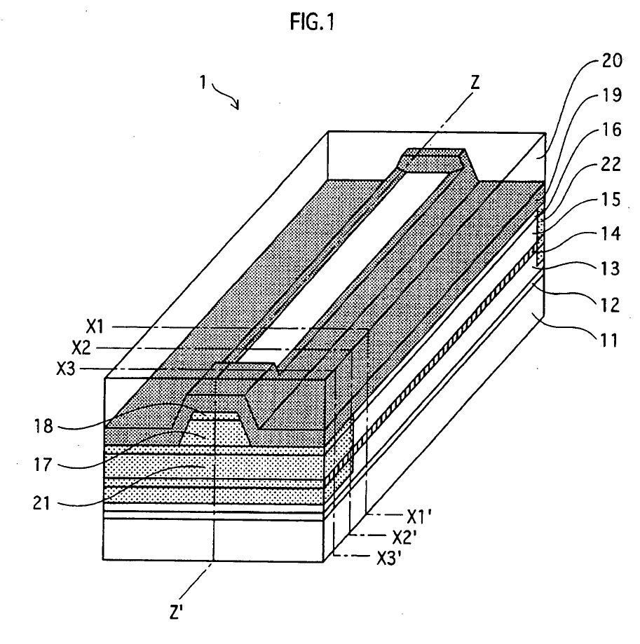

FIG. 1 is a perspective view showing a semiconductor laser device 1 according to the embodiment of the present invention.

The semiconductor laser device 1 is formed by laminating an n-type semiconductor substrate 11, an n-type buffer layer 12, an n-type cladding layer 13, a quantum well active layer 14, a p-type first cladding layer 15, an etching stop layer 16, a p-type second cladding layer 17, a p-type cap layer 18, a current blocking layer 19, and a p-type contact layer 20, in this order. In the drawing, the p-type contact layer 20 is shown transparent for better viewing.

The n-type cladding layer 13 to the p-type second cladding layer 17 constitute an optical waveguide. A light emitting end face (the front face in FIG. 1) and an opposite end face of the optical waveguide are coated with a reflection film (not illustrated), with which an optical resonator is formed.

A reflectivity of the reflection film on the light emitting end face is set lower than a reflectivity of the reflection film on the opposite end face. As a result, a strong laser beam is emitted from the light emitting end face, whilst a weak laser beam is emitted from the opposite end face. The strong laser beam emitted from the light emitting end face is put to major use, while the weak laser beam emitted from the opposite end face is received by a light receiving element and used as a monitor of an output intensity of the laser beam emitted from the light emitting end face.

Regions of predetermined lengths from both end faces of the optical waveguide are window regions 21 and 22 which are disordered by diffusion of impurities (such as Zn) and have a larger forbidden band width (energy band gap) than a more central region of the optical waveguide.

The p-type second cladding layer 17 and the p-type cap layer 18 are extended in a resonator length direction in the form of a ridge.

The current blocking layer 19 is formed on both sides of the ridge, and over the window region 21 and the window region 22 of the optical waveguide.

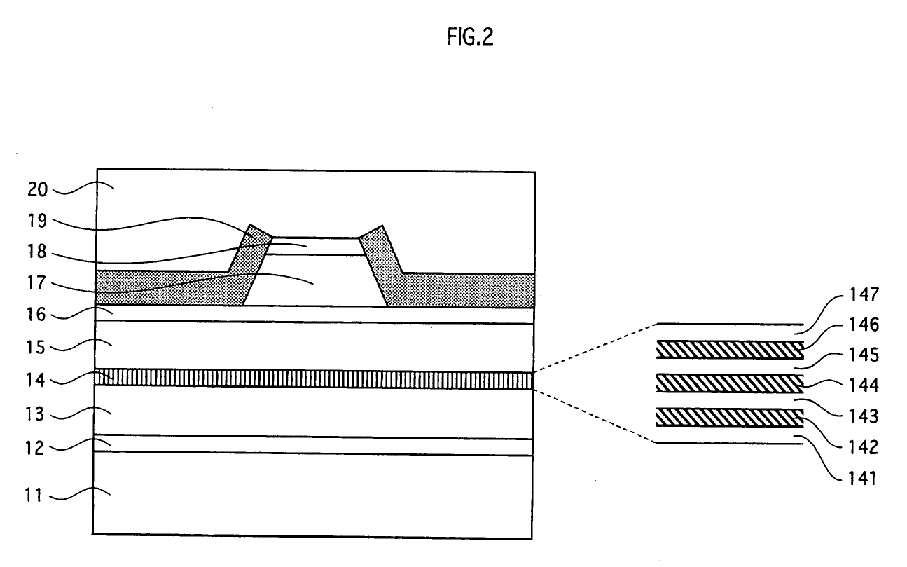

FIG. 2 shows a cross section of the semiconductor laser device 1 taken along line X1-X1′ in FIG. 1. A detailed structure of the quantum well active layer 14 is shown in the drawing.

The quantum well active layer 14 is formed by laminating an undoped guide layer 141, an undoped well layer 142, an undoped barrier layer 143, an undoped well layer 144, an undoped barrier layer 145, an undoped well layer 146, and an undoped guide layer 147, in this order.

Favorable film thickness, composition, and carrier concentration of each layer in this embodiment are shown in TABLE 1 below.

TABLE 1

| | | film thickness | | carrier |
|---|---|---|---|---|
| sign | layer name | (μm) | composition | concentration (cm⁻²) |
| 20 | p-type GaAs | 4 | p-GaAs | 2 × 10¹⁸ |
| | contact layer | | | |
| 19 | n-type AlInP | 0.4 | n-Al_{0.51}In_{0.49}P | 2 × 10¹⁸ |
| | current | | | |
| | blocking layer | | | |
| 18 | p-type GaInP cap | 0.05 | p-Ga_{0.51}In_{0.49}P | 2 × 10¹⁸ |
| | layer | | | |
| 17 | p-type AlGaInP | 1 | p-(Al_{0.7}Ga_{0.3})_{0.51}In_{0.49}P | 1 × 10¹⁸ |
| | second cladding | | | |
| | layer | | | |
| 16 | p-type GaInP | 0.01 | p-Ga_{0.56}In_{0.44}P | 2 × 10¹⁸ |
| | etching stop | | | |
| | layer | | | |
| 15 | p-type AlGaInP | 0.2 | p-(Al_{0.7}Ga_{0.3})_{0.51}In_{0.49}P | 5 × 10¹⁷ |
| | first cladding | | | |
| | layer | | | |
| 147 | guide layer | 0.025 | un-(Al_{0.5}Ga_{0.5})_{0.51}In_{0.49}P | |
| 146 | well layer | 0.005 | un-Ga_{0.46}In_{0.54}P | |
| 145 | barrier layer | 0.005 | un-(Al_{0.5}Ga_{0.5})_{0.51}In_{0.49}P | |
| 144 | well layer | 0.005 | un-Ga_{0.46}In_{0.54}P | |
| 143 | barrier layer | 0.005 | un-(Al_{0.5}Ga_{0.5})_{0.51}In_{0.49}P | |
| 142 | well layer | 0.005 | un-Ga_{0.46}In_{0.54}P | |
| 141 | guide layer | 0.025 | un-(Al_{0.5}Ga_{0.5})_{0.51}In_{0.49}P | |
| 13 | n-type AlGaInP | 2 | n-(Al_{0.7}Ga_{0.3})_{0.51}In_{0.49}P | 1 × 10¹⁸ |
| | cladding layer | | | |
| 12 | n-type GaAs | 0.5 | n-GaAs | 1 × 10¹⁸ |
| | buffer layer | | | |
| 11 | n-type GaAs | 120 | n-GaAs | 2 × 10¹⁸ |
| | substrate | | | |

<Forms of the Window Regions 21 and 22 and the Current Blocking Layer 19>

It is conventionally known that a window region and a current blocking layer which covers the window region have a function of preventing COD (Catastrophic Optical Damage) of an end face of an optical waveguide. A technique of symmetrically providing a window region and a current blocking layer which covers the window region in both end areas of a semiconductor laser device so as to have a substantially same length from the corresponding end face is well known as a COD prevention measure.

The semiconductor laser device 1 differs from this conventional construction in that the window region 21 on the light emitting end face side and the current blocking layer 19 covering the window region 21 are formed asymmetrically with the window region 22 on the opposite end face side and the current blocking layer 19 covering the window region 22. In more detail, the window region 21 and the current blocking layer 19 covering the window region 21 are formed larger than the window region 22 and the current blocking layer 19 covering the window region 22.

The inventors of the present invention confirmed that the semiconductor laser device 1 of this construction emitted a laser beam having a larger horizontal divergence angle θ∥ than in the conventional art. Effects and property data of this construction will be described in detail later.

<Manufacturing Method of the Semiconductor Laser Device 1>

The semiconductor laser device 1 has a form similar to a conventional typical ridge-type semiconductor laser device, and so can be manufactured using a well-known method. For example, the semiconductor laser device 1 may be manufactured in the following manner.

The n-type buffer layer 12 to the p-type cap layer 18 are grown on the n-type semiconductor substrate 11. After this, impurities (such as Zn) are diffused in both end areas to form the window regions 21 and 22. Furthermore, a dielectric insulating film of SiO2 or the like is formed on an entire surface. Then the p-type second cladding layer 17 and the p-type cap layer 18 on both sides of a strip-shaped area which is to serve as an upper surface of the ridge are etched while leaving SiO2 only in the strip-shaped area, by photolithography. Following this, the dielectric film on the light emitting end face side of the strip-shaped area is removed with a larger amount than the dielectric film on the opposite end face side of the strip-shaped area, and the current blocking layer 19 is selectively grown using remaining SiO2 as a mask. Lastly, the whole dielectric film is removed and the p-type contact layer 20 is grown.

<Beam Shaping Region and its Effects>

The following explains how the semiconductor laser device 1 with the above construction emits a laser beam having a larger horizontal divergence angle θ∥ than in the conventional art.

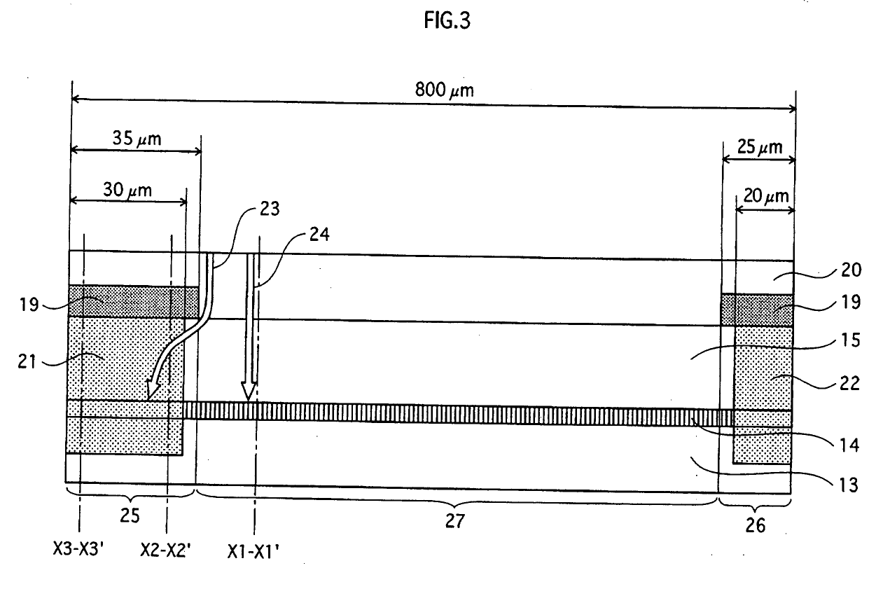

FIG. 3 is a conceptual view showing flows of carriers (electron holes) in a longitudinal section of the semiconductor laser device 1 taken along line Z-Z′ in FIG. 1. A main part of the semiconductor laser device 1 in the Z-Z′ longitudinal section is shown in the drawing, with the light emitting end face being located on the left side.

Here, a region in the optical waveguide which is covered by the current blocking layer 19 and to which a current is not directly injected from then-type contact layer 20 is called a current uninjected region (also called a beam shaping region based on its function).

As shown in FIG. 3, a total length of the optical resonator is 800 μm. The optical waveguide is divided into a current uninjected region 25 which is 35 μm long from the light emitting end face, a current uninjected region 26 which is 25 μm long from the opposite end face, and a gain region 27 other than the current uninjected regions 25 and 26. The window region 21 is included in the current uninjected region 25, and the window region 22 is included in the current uninjected region 26.

In FIG. 3, arrow 23 indicates flows of carriers in one end area of the gain region 27, whereas arrow 24 indicates flows of carriers in a more central area of the gain region 27. Carriers which are injected into the end area of the gain region 27 spread and flow into the current uninjected region 25 and the window region 21, under the influence of a low resistance state of the window region 21 induced by diffusion of impurities.

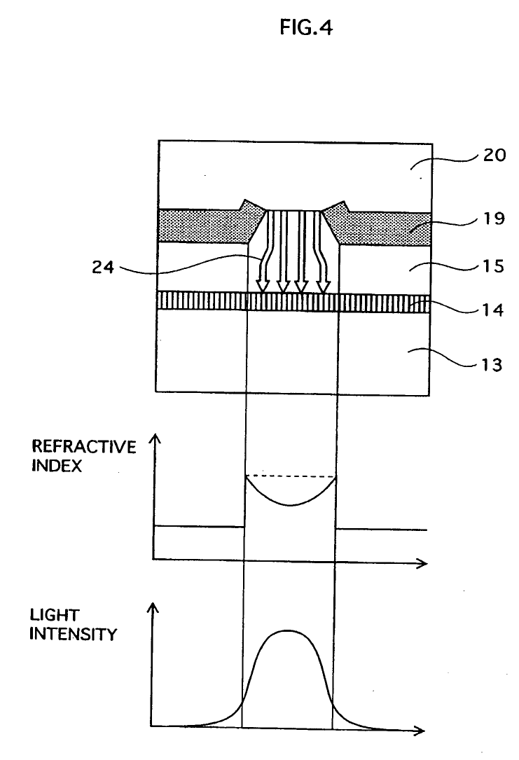

FIG. 4 is a conceptual view showing flows of carriers, a refractive index of the active layer 14, and a light intensity of a near-field pattern in the cross section of the semiconductor laser device 1 taken along line X1-X1′.

The p-type cladding layer and the n-type cladding layer in the X1-X1′ cross section are not in a low resistance state (i.e. are not made into a window). Accordingly, carriers do not spread much and concentrate in a ridge width center. It is known that, when carriers are injected into the active layer 14, a refractive index of the active layer 14 drops due to a plasma effect, and optical confinement weakens in an area where the refractive index drops. In the X-X′ cross section, however, the weakening of the optical confinement is limited only to the ridge width center, and the light intensity of the near-field pattern relatively concentrates in the ridge width center.

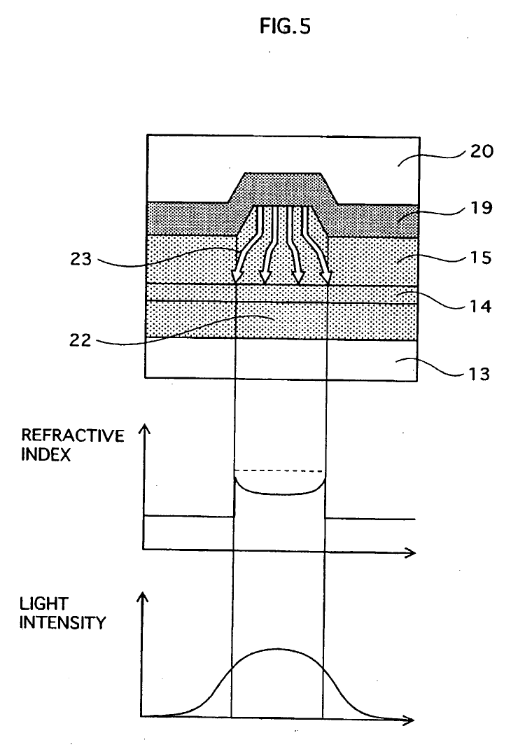

FIG. 5 is a conceptual view showing flows of carriers, a refractive index of the active layer 14, and a light intensity of a near-field pattern in a cross section of the semiconductor laser device 1 taken along line X2-X2′ in FIG. 1.

The p-type cladding layer and the n-type cladding layer in the X2-X2′ cross section are in a low resistance state (i.e. are made into a window). Accordingly, carriers flowing in from the end area of the gain region 27 spread throughout the ridge width. This being so, the refractive index drops and the optical confinement weakens throughout the ridge width, and the light intensity of the near-field pattern is widely distributed.

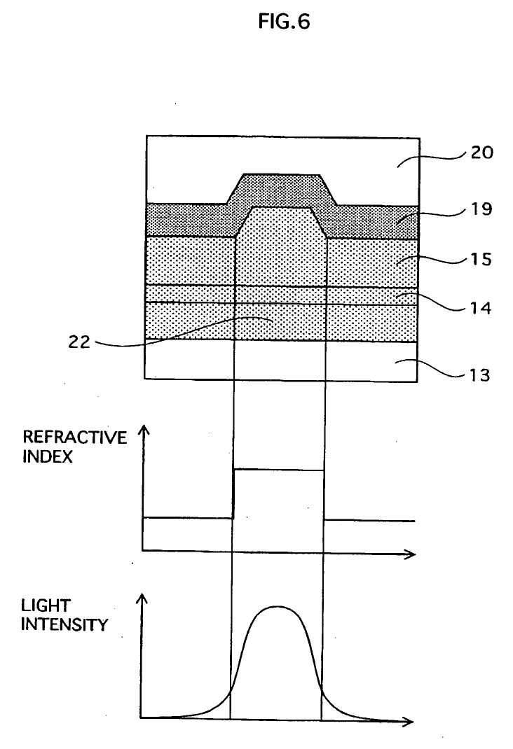

FIG. 6 is a conceptual view showing flows of carriers, a refractive index of the active layer 14, and a light intensity of a near-field pattern in a cross section of the semiconductor laser device 1 taken along line X3-X3′ in FIG. 1.

The p-type cladding layer and the n-type cladding layer in the X3-X3′ cross section are in a low resistance state (i.e. are made into a window) However, the current uninjected region 25 has a length of 35 μm from the light emitting end face. This length is sufficient for preventing carriers, which flow in from the end area of the gain region 27, from reaching the light emitting end face. Accordingly, there is no area where the optical confinement weakens in the X3-X3′ cross section, and the light intensity of the near-field pattern heavily concentrates in the ridge width center.

Thus, the semiconductor laser device 1 is constructed so that the current uninjected region 25 on the light emitting end face side is long enough to keep carriers, which flow from the end area of the gain region 27 into the window region 21, from reaching the light emitting end face. In this way, the light intensity of the near-field pattern on the light emitting end face heavily concentrates in the ridge width center, as a result of which a laser beam having a large horizontal divergence angle θ∥ is produced.

Note here that, to ensure a sufficient gain region length for favorable light output power, the current uninjected region 25 on the light emitting end face side is preferably longer than the current uninjected region 26 on the opposite end face side, and a total length of the two current uninjected regions 25 and 26 preferably does not exceed 10% of the total length of the optical resonator.

Also, since the length of the window region 21 on the light emitting end face side is equal to or smaller than the length of the current uninjected region 25 on the light emitting end face side, the length of the window region 21 preferably does not exceed 10% of the total length of the optical resonator.

<Properties>

The inventors of the present invention produced a plurality of semiconductor laser devices for an experiment. The produced semiconductor laser devices all have the cross sectional construction shown in FIG. 203 and TABLE 1, with the total length of the optical resonator being 800 μm and the sum of the lengths of the current uninjected regions on both end face sides being 60 μm. The semiconductor laser devices each differ in length of the current uninjected region on the light emitting end face side.

Data of various properties obtained as a result of the experiment using these semiconductor laser devices is shown below. Hereafter, the length of the current uninjected region on the light emitting end face side is referred to as a beam shaping region length.

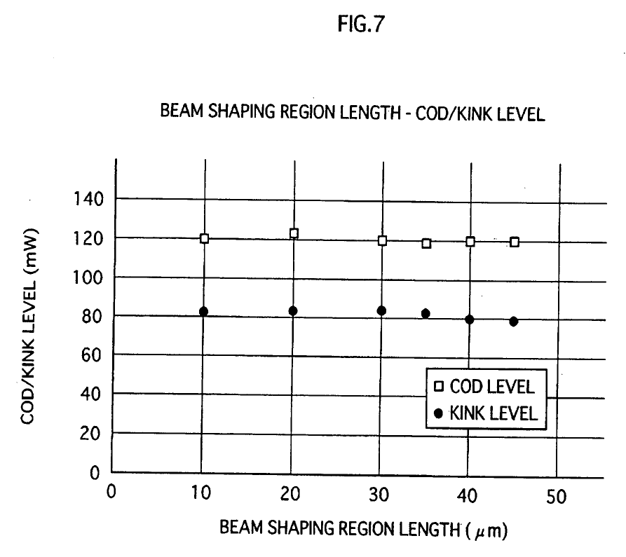

FIG. 7 is a graph showing a relationship between the beam shaping region length and COD and kink levels.

As shown in the drawing, the beam shaping region length did not affect any of the COD level and the kink level.

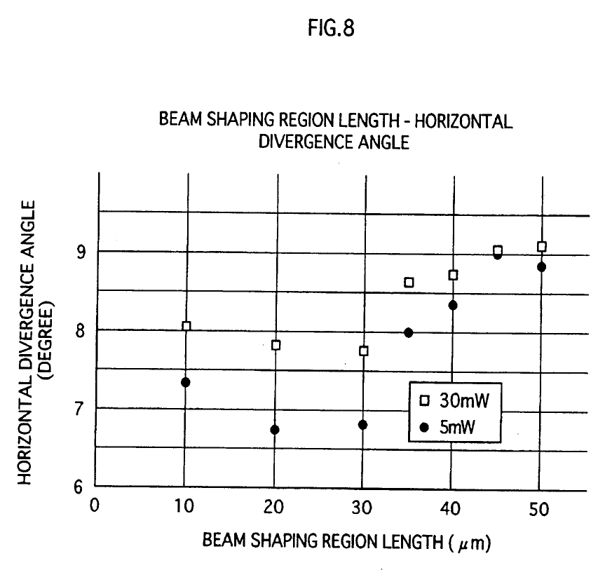

FIG. 8 is a graph showing a relationship between the beam shaping region length and the horizontal divergence angle.

As shown in the drawing, when the beam shaping region length is 30 μm or more, the horizontal divergence angle was larger than when the beam shaping region length is below 30 μm. Also, when the beam shaping region length is 35 μm or more, (1) the horizontal divergence angle increased by about one degree in both cases of 30 mW output power and 5 mW output power, and (2) variations in horizontal divergence angle when the output power changes were reduced.

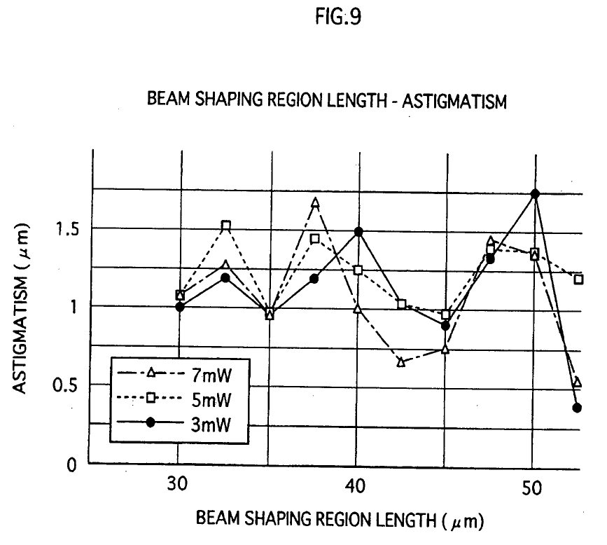

FIG. 9 is a graph showing a relationship between the beam shaping region length and an astigmatism.

As shown in the drawing, when the beam shaping region length is 45 μm or less, variations in astigmatism when the output power changes were relatively small.

The above property data indicates that, by favorably designing the cross sectional construction of the semiconductor laser device and the gain region length to attain desired COD and kink levels and, independently of this, setting the beam shaping region length at 35 μm or more, a laser beam having a larger horizontal divergence angle than in the conventional art can be produced without decreasing the COD and kink levels.

Also, by setting the beam shaping region length at 35 μm or more, variations in horizontal divergence angle according to light output power are reduced, with it being possible to reduce design margins for maximum light output power and an optical system.

Thus, the horizontal divergence angle can be managed independently of the properties that are dependent on the cross sectional construction and the gain region length. Also, variations in horizontal divergence angle according to light output power can be reduced. This enables efficient designing of semiconductor laser devices. Hence semiconductor laser devices having favorable characteristics can be designed more easily than in the conventional art.

<Example Application to a Dual Wavelength Semiconductor Laser Device>

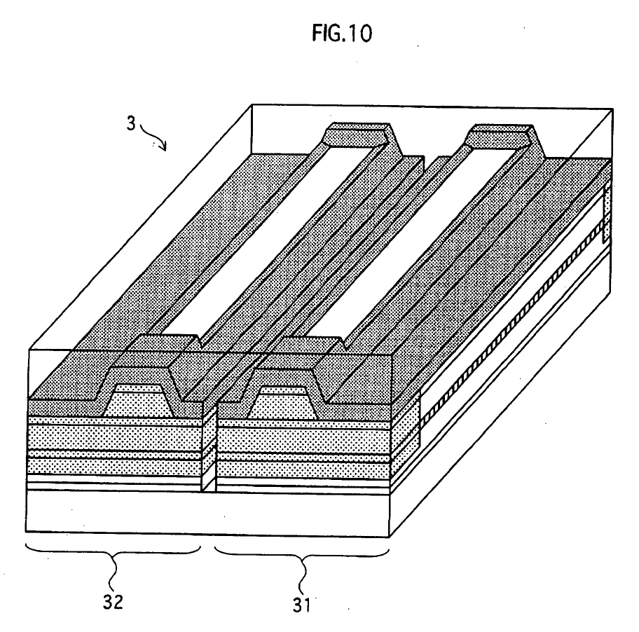

FIG. 10 is a perspective view showing a dual wavelength semiconductor laser device 3 to which the above construction of the semiconductor laser device 1 is applied.

The dual wavelength semiconductor laser device 3 is formed by disposing an AlGaAs infrared semiconductor laser device 31 and an InGaAlP infrared semiconductor laser device 32 on a single n-GaAs substrate, using a monolithic integration process.

The dual wavelength semiconductor laser device 3 is characterized in that at least one of the infrared semiconductor laser devices 31 and 32 has a larger current uninjected region on the light emitting end face side than on the opposite end face side.

A manufacturing method of a dual wavelength semiconductor laser device using the monolithic integration process is disclosed, for example, in Japanese Patent Application Publication No. 2001-217504.

<Example Application to a Groove-Type Semiconductor Laser Device>

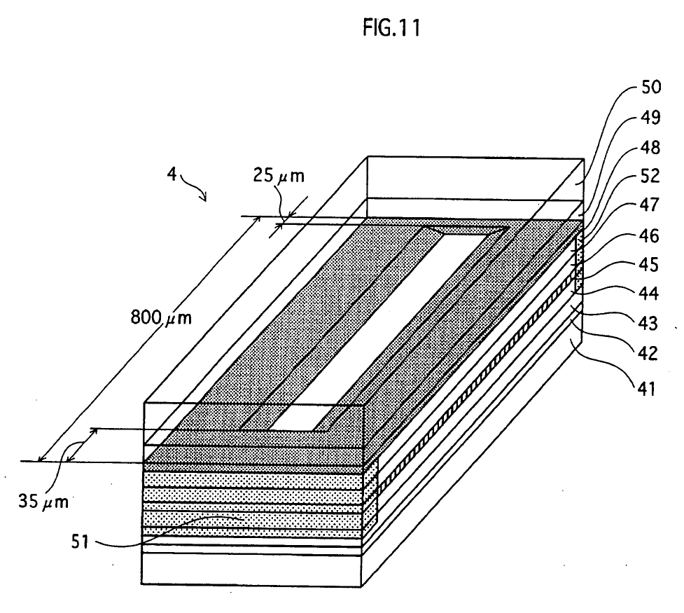

FIG. 11 is a perspective view showing a groove-type semiconductor laser device 4 to which the above construction of the semiconductor laser device 1 is applied.

The groove-type semiconductor laser device 4 is formed by laminating a GaAs substrate 41, a buffer layer 42, an n-type first cladding layer 43, an n-type second cladding layer 44, a quantum well active layer 45, a p-type first cladding layer 46, a p-type second cladding layer 47, a current blocking layer 48, a p-type third cladding layer 49, and a contact layer 50, in this order. In the drawing, the p-type third cladding layer 49 and the contact layer 50 are shown transparent for better viewing.

The n-type first cladding layer 43 to the p-type third cladding layer 49 constitute an optical waveguide. A light emitting end face (the front face in FIG. 11) and an opposite end face of the optical waveguide are coated with a reflection film (not illustrated), with which an optical resonator is formed.

Regions 51 and 52 of predetermined lengths from both end faces of the optical waveguide are window regions formed by disordering.

The current blocking layer 48 is sandwiched between the p-type second cladding layer 47 and the p-type third cladding layer 49, except in a central part of a strip-shaped area that extends across a total length of the optical resonator.

As shown in the drawing, the total length of the optical resonator is 800 μm. The current blocking layer 48 is provided in an area which is 35 μm long from the light emitting end face of the optical waveguide and in an area which is 25 μm long from the opposite end face of the optical waveguide. A resulting current uninjected region on the light emitting end face side is provided with a beam shaping function.

<Example Application to a Blue-Violet Semiconductor Laser Device>

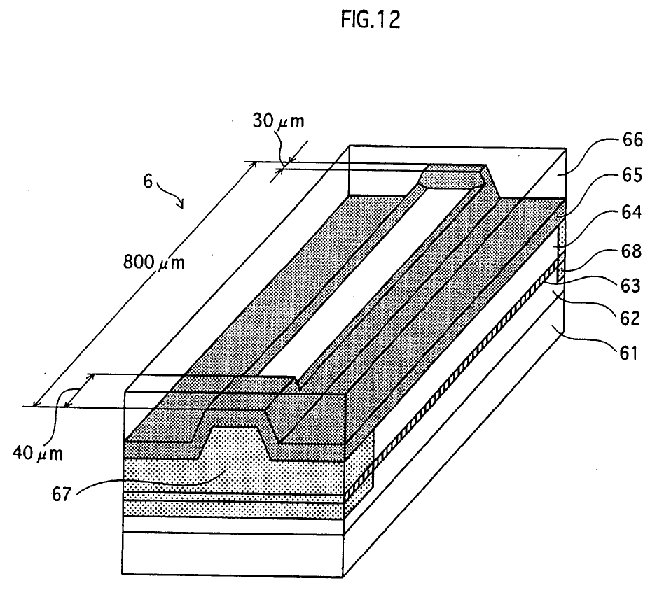

FIG. 12 is a perspective view showing a blue-violet semiconductor laser device 6 to which the above construction of the semiconductor laser device 1 is applied.

The blue-violet semiconductor laser device 6 is formed by laminating an n-type GaN substrate 61, an n-type AlGaN cladding layer 62, a quantum well active layer 63, a p-type AlGaN cladding layer 64, a current blocking layer 65, and a p-type GaN contact layer 66, in this order. In the drawing, the p-type GaN contact layer 66 is shown transparent for better viewing.

The n-type AlGaN cladding layer 62 to the p-type AlGaN cladding layer 64 constitute an optical waveguide. A light emitting end face (the front face in FIG. 12) and an opposite end face of the optical waveguide are coated with a reflection film (not illustrated), with which an optical resonator is formed.

Regions 67 and 68 of predetermined lengths from both end faces of the optical waveguide are window regions formed by disordering.

As shown in the drawing, a total length of the optical resonator is 800 μm. The current blocking layer 65 covers an area which is 40 μm long from the light emitting end face of the optical waveguide and an area which is 30 μm long from the opposite end face of the optical waveguide. A resulting current uninjected region on the light emitting end face side is provided with a beam shaping function.

As exampled above, the semiconductor laser device according to the present invention is suitable for use in an optical pickup of an optical disc device, as one example.

Although the present invention has been fully described by way of examples with reference to the accompanying drawings, it is to be noted that various changes and modifications will be apparent to those skilled in the art.

Therefore, unless such changes and modifications depart from the scope of the present invention, they should be construed as being included therein.

What is claimed is:

1. A semiconductor laser device including an optical resonator,
the optical resonator comprising:
an optical waveguide formed by laminating a cladding layer of a first conductivity type, an active layer, and a cladding layer of a second conductivity type in the stated order; and
a pair of reflection planes formed by providing both a light emitting end face and an opposite end face of the optical waveguide with a reflection function,
wherein a window region is formed in, of both end areas of the optical waveguide, at least an end area including the light emitting end face, by introduction of impurities, and
a length of the window region in the end area including the light emitting end face, measured in a resonator length direction, is set to prevent carriers which flow from a current injected region of the optical waveguide into the window region, from reaching the light emitting end face.

2. A semiconductor laser device including an optical resonator,
the optical resonator comprising:
an optical waveguide formed by laminating a cladding layer of a first conductivity type, an active layer, and a cladding layer of a second conductivity type in the stated order; and
a pair of reflection planes formed by providing both a light emitting end face and an opposite end face of the optical waveguide with a reflection function,
wherein the optical waveguide includes:
a gain region to which a current is to be injected; and
a window region which is formed in, of both end areas of the optical waveguide, at least an end area including the light emitting end face, by introduction of impurities, and
a length of the window region in the end area including the light emitting end face, measured in a resonator length direction, is set to prevent carriers which are injected at an end of the gain region, from reaching the light emitting end face.

3. The semiconductor laser device of claim 1,
wherein a current uninjected region is formed in the end area including the light emitting end face, and
the window region is included in the current uninjected region.

4. The semiconductor laser device of claim 3,
wherein the current uninjected region is covered by a current blocking layer.

5. The semiconductor laser device of claim 3,
wherein a length of the current uninjected region, measured in the resonator length direction, is set to prevent carriers which flow from the current injected region of the optical waveguide into the current uninjected region, from reaching the light emitting end face.

6. The semiconductor laser device of claim 5,
wherein the length of the current uninjected region is no smaller than 35 μm.

7. The semiconductor laser device of claim 5,
wherein the length of the current uninjected region is no greater than 45 μm.

8. The semiconductor laser device of claim 1,
wherein in addition to the window region in the end area including the light emitting end face, a window region is formed in an end area including the opposite end face, by introduction of impurities.

9. The semiconductor laser device of claim 8,
wherein the window region in the end area including the light emitting end face is longer than the window region in the end area including the opposite end face.

10. The semiconductor laser device of claim 8,
wherein the window region in the end area including the opposite end face is included in a current uninjected region formed in the optical waveguide.

11. The semiconductor laser device of claim 10,
wherein a total current uninjected region length that includes a length of the current uninjected region is no greater than 10% of a total length of the optical resonator.

12. A semiconductor laser device including an optical resonator,
the optical resonator comprising:
an optical waveguide formed by laminating a cladding layer of a first conductivity type, an active layer, and a cladding layer of a second conductivity type in the stated order; and
a pair of reflection planes formed by providing both a light emitting end face and an opposite end face of the optical waveguide with a reflection function,
wherein a window region is formed in, of both end areas of the optical waveguide, at least an end area including the light emitting end face, by introduction of impurities, and
a length of the window region in the end area including the light emitting end face, measured in a resonator length direction, is no smaller than 30 μm.

13. A semiconductor laser device including an optical resonator,
the optical resonator comprising:
an optical waveguide formed by laminating a cladding layer of a first conductivity type, an active layer, and a cladding layer of a second conductivity type in the stated order; and
a pair of reflection planes formed by providing both a light emitting end face and an opposite end face of the optical waveguide with a reflection function,
wherein a window region is formed in, of both end areas of the optical waveguide, at least an end area including the light emitting end face, by introduction of impurities, and
a length of the window region in the end area including the light emitting end face, measured in a resonator length direction, is no greater than 10% of a total length of the optical resonator.

14. A semiconductor laser device including an optical resonator,
the optical resonator comprising:
an optical waveguide formed by laminating a cladding layer of a first conductivity type, an active layer, and a cladding layer of a second conductivity type in the stated order; and
a pair of reflection planes formed by providing both a light emitting end face and an opposite end face of the optical waveguide with a reflection function,
wherein a current uninjected region is formed in, of both end areas of the optical waveguide, at least an end area including the light emitting end face, and
a length of the current uninjected region in the end area including the light emitting end face, measured in a resonator length direction, is set to prevent carriers which flow from a current injected region of the optical waveguide into the current uninjected region, from reaching the light emitting end face.

15. The semiconductor laser device of claim 14,
wherein a window region is formed in the current uninjected region by introduction of impurities.

16. A semiconductor laser device including an optical resonator,
the optical resonator comprising:
an optical waveguide formed by laminating a cladding layer of a first conductivity type, an active layer, and a cladding layer of a second conductivity type in the stated order; and
a pair of reflection planes formed by providing both a light emitting end face and an opposite end face of the optical waveguide with a reflection function,
wherein a current uninjected region is formed in, of both end areas of the optical waveguide, at least an end area including the light emitting end face, and
a length of the current uninjected region in the end area including the light emitting end face, measured in a resonator length direction, is no smaller than 35 μm.

17. The semiconductor laser device of claim 16,
wherein a window region is formed in the current uninjected region by introduction of impurities.

18. A semiconductor laser device including an optical resonator,
the optical resonator comprising:
an optical waveguide formed by laminating a cladding layer of a first conductivity type, an active layer, and a cladding layer of a second conductivity type in the stated order; and
a pair of reflection planes formed by providing both a light emitting end face and an opposite end face of the optical waveguide with a reflection function,
wherein a current uninjected region is formed in, of both end areas of the optical waveguide, at least an end area including the light emitting end face, and
a length of the current uninjected region in the end area including the light emitting end face, measured in a resonator length direction, is no greater than 45 μm.

19. The semiconductor laser device of claim 18,
wherein a window region is formed in the current uninjected region by introduction of impurities.
